(19) United States
(12) Patent Application Publication
(10) Pub. No.: US 2007/0212849 A1
(43) Pub. Date: Sep. 13, 2007

(54) Method of fabricating a groove-like structure in a semiconductor device

(76) Inventors: Frank Ludwig, Dresden (DE); Kimberly Wilson, Dresden (DE); Arabinda Das, Dresden (DE); Hans-Peter Sperlich, Dresden (DE); Andreas Klipp, Dresden (DE); Kristin Schupke, Dresden (DE)

Correspondence Address: SLATER & MATSIL LLP, 17950 PRESTON ROAD, SUITE 1000, DALLAS, TX, 75252, US

(21) Appl. No.: 11/373,064

(22) Filed: Mar. 10, 2006

(51) Int. Cl. H01L 21/76

(52) U.S. Cl. 438/424; 257/E21.547

(57) ABSTRACT

The present invention relates to a method of fabricating a groove-like structure in a semiconductor device including etching a trench in a substrate, filling the trench with a spin-on-glass liquid forming a spin-on-glass liquid layer containing a solvent, baking the spin-on-glass liquid layer in order to remove the solvent and forming a baked layer, etching the baked layer to a predetermined depth using an etchant that provides a larger etch rate with regard to silicon than with regard to silicon nitride or silicon oxide, and, after etching the baked layer, annealing the remaining baked layer and forming a spin-on-glass oxide layer inside the trench.

### TECHNICAL FIELD

The present invention relates to a method of fabricating a groove-like structure in a semiconductor device. More specifically, the invention relates to a method wherein an etched trench is filled with a spin-on-glass liquid.

### BACKGROUND

U.S. Pat. No. 6,566,229 describes a method of forming a groove-like structure wherein a trench is etched into a substrate. After etching, the trench is filled with a spin-on-glass liquid. The liquid is subjected to baking and annealing such that a spin-on-glass oxide layer is formed inside the trench. Then, the spin-on-glass oxide layer is etched down to a predetermined depth leaving the bottom of the trench coated with the spin-on-glass oxide layer. During this etch step buffered hydrofluoric acid is applied, which has a large etch rate in silicon oxide. Afterwards, a second silicon oxide layer is deposited on top of the etched spin-on-glass oxide layer using a CVD technique. After formation of the second oxide layer a planarization step is carried out using a CMP (chemical mechanical polishing) step so as to complete the groove-like structure.

U.S. Patent Application Publication 2003/0030121 describes a further method of forming a groove-like structure, which is quite similar to that of U.S. Pat. No. 6,566,229. After baking and annealing of the spin-on-glass liquid the resulting spin-on-glass oxide layer is etched using hydrofluoric acid and covered thereafter with an HDP (high density plasma) oxide.

### SUMMARY OF THE INVENTION

With regard to prior art methods, it turned out that the etch rate of hydrofluoric acid in a baked and annealed spin-on-glass oxide layer strongly depends on the aspect ratio of the trench where the spin-on-glass oxide layer is formed. The inventors observed that the etch rate of hydrofluoric acid in trenches with a large aspect ratio is faster than in trenches with a small aspect ratio. Accordingly, one aspect of the invention avoids this effect and provides a method that results in a uniform spin-on-glass oxide layer thickness in trenches independent of their aspect ratio.

A second aspect of the present invention provides a method that allows simultaneously etching trenches of a uniform depth that extend through both silicon and spin-on-glass oxide areas. Trenches of this kind may be useful for word lines of a memory device as will be more apparent from the explications hereinafter.

According to embodiments of the present invention, fabricating a groove-like structure in a semiconductor device includes etching a trench in a substrate, filling the trench with a spin-on-glass liquid forming a spin-on-glass liquid layer containing a solvent, baking the spin-on-glass liquid layer in order to remove the solvent thus forming a baked layer, etching the baked layer to a predetermined depth using an etchant that provides a larger etch rate with regard to silicon than with regard to silicon nitride or silicon oxide, and after etching the baked layer, annealing the remaining baked layer thus forming a spin-on-glass oxide layer inside the trench.

According to embodiments of the invention, the spin-on-glass is etched before annealing providing a very uniform etch rate in trenches with large and small aspect ratios. The uniform etch rate results from the fact that a baked and not yet annealed spin-on-glass layer does not suffer from thermal stress. The step of annealing induces a significant amount of thermal stress inside the annealed layer. This stress is different in trenches with large aspect ratios than in trenches with small aspect ratios. Thermal stress, however, strongly influences the etch rate of the annealed spin-on-glass oxide layer such that the etch rate in trenches will largely vary after annealing. Before annealing however, the amount of thermal and mechanical stress inside the baked layer is still quite small compared to the annealed layer resulting in uniform etch rates that are very independent from the aspect ratio of the respective trench.

Before annealing, the etch behavior of the baked layer is very similar to that of a polysilicon layer. Accordingly, an etchant that provides a larger etch rate with regard to silicon than with regard to silicon nitride or silicon oxide provides much better etch results than etchants commonly used for oxide layers.

According to a first preferred embodiment of the invention, an etch mask is formed on top of the structure before etching the baked layer such that at least a part of the substrate and at least a part of the baked layer is exposed. Then the exposed part of the baked layer and the exposed part of the substrate are etched using an etchant that provides identical or at least very similar etch rates in the substrate and in the baked layer. The substrate may be a silicon substrate and the etchant preferably provides identical or at least very similar etch rates in silicon and in the baked layer.

According to a preferred aspect of the invention, at least two parallel trenches are etched in the silicon substrate wherein the trenches enclose a stripe-like active area therebetween. The two parallel trenches are filled with the spin-on-glass liquid and the resulting spin-on-glass liquid layer is baked. Then, the etch mask is formed on top of the structure such that at least one stripe-like zone is exposed, which defines a future word line of a memory device. The stripe like zone is preferably perpendicular or inclined relative to the stripe-like active area.

Preferably, a plurality of transistors is fabricated in the stripe-like active area each of which belongs to a memory cell of the memory device.

The etch mask may be formed on top of the structure such that a plurality of parallel stripe-like zones is exposed each of which defines a future word line of the memory device and each of which is perpendicular or inclined relative to the stripe-like active area.

According to a second preferred embodiment of the invention, the baked layer is etched to a predetermined depth such that the baked layer remains in a lower region of the trench. Then, the upper region of the trench is filled with a protective isolating material after or before annealing of the baked layer.

Preferably, during the step of baking the spin-on-glass liquid layer, a polysilazane layer or a perhydro-polysilazane layer is formed.

An alkaline solution such as an ammonia containing liquid (e.g., ammonium hydroxid) may be used as etchant. Ammonium hydroxid provides the advantage that it etches polysilicon but barely silicon oxide.

The etchant is preferably free of any acid (e.g., hydrofluoric acid) since acids can significantly decrease the etchant's etch selectivity with regard to silicon and silicon oxide/nitride.

Alternatively, the step of etching the baked layer may also be carried out using an etch gas that is applied in a plasma process chamber. A suitable etch gas may contain Ar, He, N₂, Cl₂, HCl, HBr, SF₆, CF₄, NF₃ or CHF₃.

Preferably, a predefined RF source power is applied to the plasma process chamber in order to generate an isotropic etch plasma inside the chamber. A predefined RF bias power may also be applied to the plasma process chamber if an anisotropic etch behavior is required. However, the predefined RF bias power should preferably be smaller than the predefined RF bias power.

The predefined RF bias power is preferably switched off during the step of etching the baked liquid layer to the predetermined depth in order to get the best etch results.

Prior to etching the spin-on-glass liquid layer to the predetermined depth, a planarization etch step may be carried out using the same or a second etch gas that might differ from the etch gas for etching the baked layer to the predetermined depth. The second etch gas may contain Ar, He, N₂, Cl₂, HCl, HBr, SF₆, CF₄, NF₃ or CHF₃.

The RF bias power applied during the planarization step may be larger than that during the subsequent recess step wherein the baked layer is etched to its final depth. A large RF bias power reduces process time required for the planarization step.

The protective isolating material mentioned above may contain or consist of silicon oxide or silicon nitride.

The etch rate of the etchant applied during etching the baked layer to its predetermined depth is preferably at least 20 times larger with regard to silicon or polysilicon than with regard to silicon oxide or silicon nitride.

### BRIEF DESCRIPTION OF THE DRAWINGS

In order that the manner in which the above-recited and other advantages and aspects of the invention are obtained will be readily understood, a more particular description of the invention briefly described above will be rendered by reference to specific embodiments thereof, which are illustrated in the appended drawings. Understanding that these drawings depict only typical embodiments of the invention and are, therefore, not to be considered to be limiting its scope, the invention will be described and explained with additional specificity and detail through the use of the accompanying drawings in which:

FIGS. 1A-1D illustrate a method of fabricating a groove-like structure according to prior art;

FIGS. 2A-2C illustrate a first embodiment of a method according to the present invention for fabricating a groove-like structure;

FIGS. 3 and 4 show the molecular structure of perhydro-polysilazane material after baking and after annealing, respectively;

FIGS. 5A-5C illustrate a second embodiment of a method according to the present invention for fabricating a groove-like structure; and

FIGS. 6A-6B illustrate a third embodiment of a method according to the present invention for fabricating a groove-like structure.

The following list of reference symbols can be used in conjunction with the figures:
10 groove-like structure
20, 30 trench
40 substrate
50 spin-on-glass liquid layer
60, 120 spin-on-glass oxide layer
70 protective layer
100 baked layer
110 etch mask
200 upper portion
210 lower portion
300 trench
310 stripe-like active area
320 etch mask
330 stripe-like zone
340 lower region

### DETAILED DESCRIPTION OF ILLUSTRATIVE EMBODIMENTS

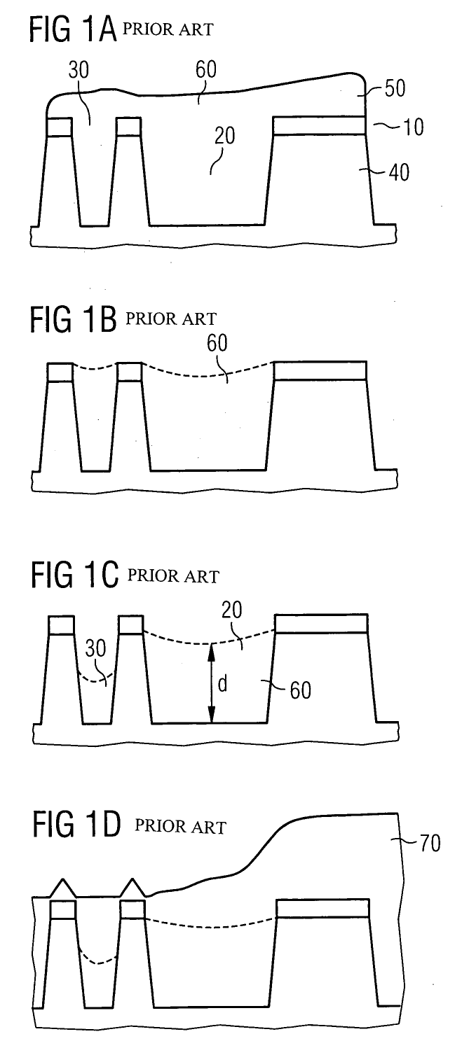

FIGS. 1A-1D illustrate a prior art method of fabricating a groove-like structure 10 in a semiconductor device.

First, trenches 20 and 30 are etched in a silicon substrate 40 of the device. The trenches are filled with a spin-on-glass liquid that forms a spin-on-glass liquid layer 50.

The spin-on-glass liquid layer 50 is subjected to baking such that a solvent contained in the spin-on-glass liquid layer is removed and a baked layer is formed. Subsequently, the baked layer is annealed yielding a spin-on-glass oxide layer 60.

Thereafter, a CMP step removes the spin-on-glass oxide layer 60 on top of the structure such that the oxide layer 60 just remains inside the trenches 20 and 30. The resulting structure is depicted in FIG. 1B.

Afterwards, the spin-on-glass oxide layer 60 is etched to a predetermined depth using an acid such as hydrofluoric acid, which is known in the art as oxide etchant. It can be seen in FIG. 1C that the etch rate in the narrow trench 30, which has a high aspect ratio, is larger than in the wide trench 20, which has a small aspect ratio. Accordingly, the remaining layer thickness d varies over the substrate 40.

Then, the remaining spin-on-glass oxide layer 60 is covered with a protective layer 70, which may consist of CVD oxide or HDP oxide layer (FIG. 1D).

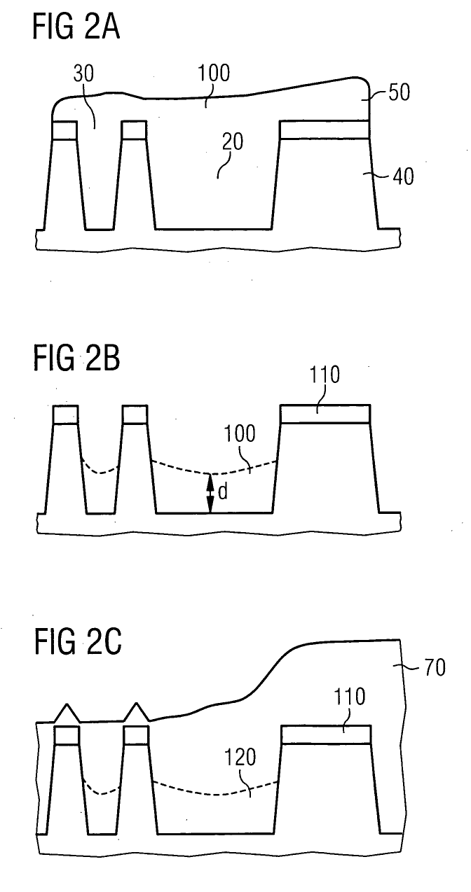

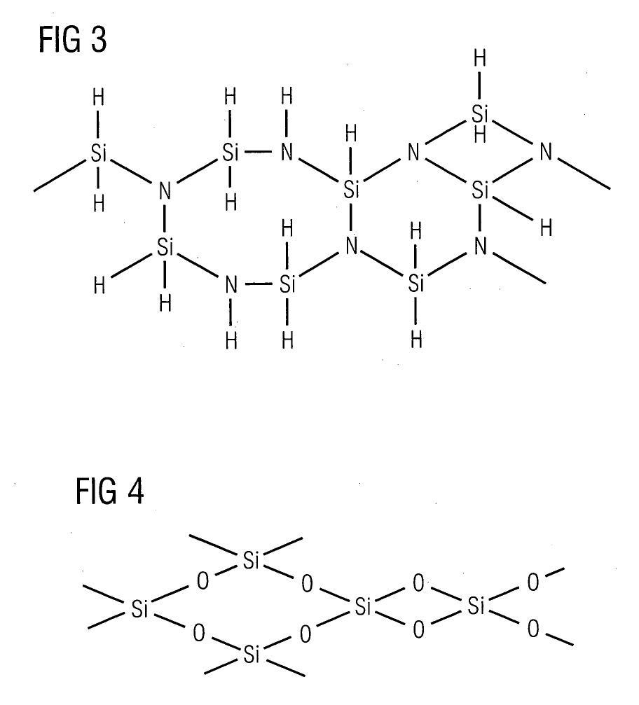

FIGS. 2A-2C illustrate a first embodiment of the invention. After etching the trenches 20 and 30 and after filling the trenches with a spin-on-glass liquid, the spin-on-glass liquid layer 50 is baked but not annealed (FIG. 2A). For example, the baked layer 100 consists of perhydro-polysilazane material (SiH₂NH)ₙ, the molecular structure of which is depicted in FIG. 3. It can be seen that the material contains H- and N-atoms, which are replaced by oxygen atoms during annealing. The annealed molecular structure is shown in FIG. 4.

Then, the baked layer 100 is etched using an etch liquid that has a larger etch rate in crystalline, polycrystalline or amorphous silicon than in silicon oxide or silicon nitride. Due to the molecular structure of polysilazane material, suitable etch liquids may comprise alkaline solutions such as pure ammonium hydroxide. In contrast to acids, alkaline solutions do not etch silicon oxide or silicon nitride at all or at least not significantly. Accordingly, these materials may be used as an etch mask 110 to cover parts of the silicon substrate 40 that are not meant to be etched.

Examples of suitable etch liquids are listed below. These liquids provide identical or at least very similar etch rates in silicon (crystalline silicon, polysilicon and amorphous silicon) and in the baked polysilazane layer 100 and show very small etch rates (or no etch rate at all) in silicon oxide or silicon nitride. It should be understood that this list is not meant to be exhaustive and that other etch liquids may have the same etch behavior like those listed below:
1. Ammonium hydroxide (NH₄OH)
2. Potassium hydroxide (KOH)
3. Tetramethylammonium (TMAH)
4. Cholin
or mixture of these.

As the baked polysilazane layer 100 is etched before annealing, the resulting layer thickness d is very homogeneous over the substrate 40. This is due to the fact, that the baked polysilazane layer 100 does not suffer from mechanical stress, which is induced by annealing and which causes different etch rates in wide and narrow trenches as discussed with regard to FIGS. 1A-1D

After etching the baked layer 100 to the predetermined depth, the baked layer 100 is annealed forming a spin-on-glass oxide layer 120. Again, the molecular structure of the annealed spin-on-glass oxide layer 120 is depicted in FIG. 4. Finally, the structure of FIG. 2C is covered with a protective layer 70 (e.g., oxide layer) as is known from prior art.

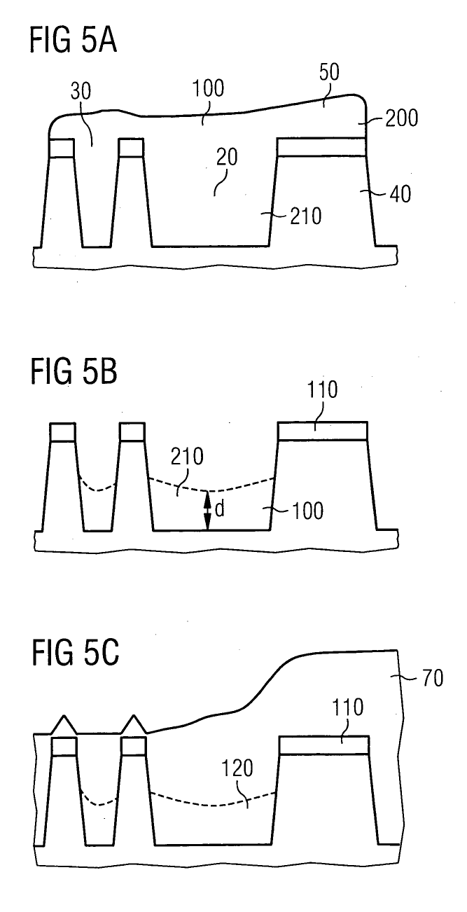

Instead of applying an etch liquid the baked layer 100 may also be dry etched in a plasma chamber using an etch gas. This is shown in FIGS. 5A-5C.

First, in a planarization step, the upper portion 200 of the baked layer 100, which extends above the surface of the substrate 40, is removed. In order to obtain an anisotropic etch behavior during the planarization step, a predefined RF bias power is applied to the plasma process chamber. The predefined RF bias power is preferably smaller than a predefined RF source power, which is simultaneously applied to the etch plasma. The RF source power is preferably coupled to the plasma via magnetic coils whereas the RF bias power is preferably coupled to the plasma in a capacitive manner via an electric chuck as is known in the art.

Etch parameters adapted to the planarization step are listed below in an exemplary fashion:
Pressure: 5-30 mT
RF source Power: 500-1000 W
RF bias Power: 50-200 W
First gas component: 10-100 sccm Ar, He and/or N₂
Second gas component: 10-60 sccm Cl₂, HCl and/or HBr
Third gas component: 10-60 sccm SF₆, CF₄, NF₃ and/or CHF₃

After completing the planarization step, a recess step is started wherein the baked layer 100 is etched in its lower portion 210 to the predetermined depth (FIG. 5B). Etch parameters for the recess etch step are listed below in an exemplary fashion:
Pressure: 5-30 mT
RF source Power: 200-800 W
RF bias Power: 0-50 W
First gas component: 10-300 sccm Ar, He and/or N₂
Second gas component: 0-50 sccm Cl₂, HCl and/or HBr
Third gas component: 10-100 sccm SF₆, CF₄, NF₃ and/or CHF₃

During the recess etch step the second gas component is preferably dropped and the RF bias Power is preferably switched off.

As discussed above, the resulting structure of FIG. 5B may be covered with a protective layer 70 (e.g., oxide layer, see FIG. 5C).

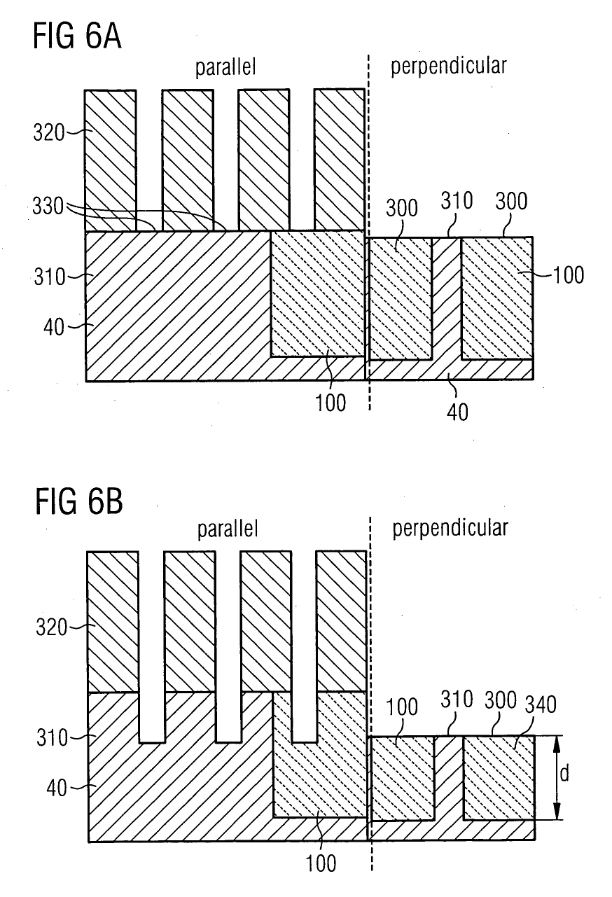

FIGS. 6A and 6B illustrate a third exemplary embodiment of the inventive method of fabricating a groove-like structure during the fabrication of a memory device.

In a first process step, at least two parallel trenches 300 are etched in a silicon substrate 40 that enclose a stripe-like active area 310 made of silicon. The two parallel trenches 300 are filled with a spin-on-glass liquid, which is baked thereafter forming a baked layer 100.

In FIG. 6A the left hand side shows a cross section, which is mainly parallel to the stripe-like active area 310. However, as the cross section is slightly inclined, the right section on the left hand side also shows the baked layer 100 that is situated adjacent to the stripe-like active area 310.

In contrast to the left hand side, the right hand side of FIG. 6A shows a cross section that is perpendicular to the stripe-like active area 310. It can be seen that the baked layer 100 fills the trenches 300 next to the stripe-like active area 310.

An etch mask 320 is formed on top of the structure such that stripe-like zones 330 are exposed that define future word lines of the memory device. The stripe-like zones 330 are basically perpendicular to the stripe-like active area 310.

Then, the structure is etched to a predetermined depth. As the stripe-like zones 330 extend over silicon areas and baked layer areas both types of material are etched simultaneously. In order to receive an etch result as shown in FIG. 6B, the etch rate of the etchant should be the same or nearly the same in silicon and in the baked layer. This objective can be accomplished by applying one of the etch parameters described above with regard to FIGS. 2A-2C and 5A-5C.

FIG. 6B shows the resulting structure after etching. It can be seen that the baked layer 100 and the etched stripe-like active silicon area 310 remain in a lower region 340 and that the remaining layer thickness d is nearly identical with regard to both materials silicon and the baked layer 100.

What is claimed is:

1. A method of fabricating a semiconductor device, the method comprising:
etching a trench in a substrate;
filling the trench with a spin-on-glass liquid forming a spin-on-glass liquid layer containing a solvent;
baking the spin-on-glass liquid layer in order to remove the solvent thus forming a baked layer;
etching the baked layer to a predetermined depth using an etchant that provides a larger etch rate with regard to silicon than with regard to silicon nitride or silicon oxide; and
after etching the baked layer, annealing the remaining baked layer to form a spin-on-glass oxide layer inside the trench.

2. The method as claimed in claim 1, further comprising:
before etching the baked layer, forming an etch mask over the substrate such that at least a part of the substrate and at least a part of the baked layer is exposed;
wherein the exposed part of the baked layer and the exposed part of the substrate are etched using an etchant that provides identical or at least very similar etch rates in the substrate and in the baked layer.

3. The method as claimed in claim 2, wherein
the substrate comprises a silicon substrate; and
the exposed part of the baked layer and the exposed part of the silicon substrate are etched using an etchant that provides identical or at least very similar etch rates in silicon and in the baked layer.

4. The method as claimed in claim 3, wherein:
etching a trench comprises etching at least two parallel trenches in the silicon substrate, the parallel trenches enclosing a stripe-like active area therebetween;
filling the trench comprises filling the two parallel trenches with the spin-on-glass liquid; and
forming an etch mask comprises forming the etch mask over the substrate such that at least one stripe-like zone is exposed, the at least one stripe-like zone defining a future word line of a memory device, the stripe-like zone being perpendicular or inclined relative to the stripe-like active area.

5. The method as claimed in claim 4, further comprising fabricating a plurality of transistors in the stripe-like active area, each transistor belonging to a memory cell of the memory device.

6. The method as claimed in claim 3, wherein forming an etch mask comprises forming the etch mask over the substrate such that a plurality of parallel stripe-like zones are exposed, each stripe-like zone defining a future word line of the memory device and being perpendicular or inclined relative to the stripe-like active area.

7. The method as claimed in claim 1, wherein etching the baked layer comprises etching the baked layer to a predetermined depth such that the baked layer remains in a lower region of the trench, the method further comprising filling an upper region of the trench with a protective isolating material before or after annealing the remaining baked layer.

8. The method as claimed in claim 1, wherein during the step of baking the spin-on-glass liquid layer a polysilazane layer is formed.

9. The method as claimed in claim 8, wherein baking the spin-on-glass liquid layer comprises forming a perhydro-polysilazane layer.

10. The method as claimed in claim 1, wherein the etchant comprises an alkaline solution.

11. The method as claimed in claim 10, wherein the etchant comprises an ammonia-containing liquid.

12. The method as claimed in claim 10, wherein the alkaline solution contains ammonium hydroxide.

13. The method as claimed in claim 1, wherein etching the baked layer is carried out using an etch gas.

14. The method as claimed in claim 13, wherein said etch gas contains Ar, He, N₂, Cl₂, HCl, HBr, SF₆, CF₄, NF₃ or CHF₃.

15. The method as claimed in claim 13, wherein etching the baked layer comprises etching the baked layer in a plasma process chamber.

16. The method as claimed in claim 15, wherein etching the baked layer comprises applying a predefined RF source power to the plasma process chamber in order to generate an isotropic etch plasma inside the chamber.

17. The method as claimed in claim 16, wherein a predefined RF bias power is applied to the plasma process chamber in order to achieve an anisotropic etch behavior, the predefined RF bias power smaller than the predefined RF source power.

18. The method as claimed in claim 17, wherein the predefined RF bias power is switched off during the step of etching the baked spin-on-glass liquid layer to the predetermined depth.

19. The method as claimed in claim 18, further comprising performing a planarization etch step prior to etching the baked layer.

20. The method as claimed in claim 19, wherein the planarization etch step is performed using a second etch gas that differs from the etch gas during the recess etch step.

21. The method as claimed in claim 20, wherein the second etch gas contains Cl₂, HCl or HBr.

22. The method as claimed in claim 20, wherein a bias power applied during the planarization etch step is larger than a bias applied during the etching of the baked layer to the predetermined depth.

23. The method as claimed in claim 7, wherein the protective isolating material comprises silicon oxide or silicon nitride.

24. The method as claimed in claim 1, wherein the etch rate of the etchant is at least 20 times larger with regard to silicon or polysilicon than with regard to silicon oxide or silicon nitride.
